(19) United States
(12) Patent Application Publication
(10) Pub. No.: US 2013/0083819 A1
(43) Pub. Date: Apr. 4, 2013

(54) METHOD FOR OPERATING AN ARC FURNACE, OSCILLATION MEASUREMENT DEVICE FOR AN ARC ELECTRODE AND CONFIGURATION FOR AN ARC FURNACE

(71) Applicant: SGL CARBON SE, Wiesbaden (DE)

(72) Inventors: THOMAS KOECK, MUENCHEN (DE); MARTIN MAYER, ALLMANNSHOFEN (DE); GEORG SCHWAIGER, NANDLSTADT (DE); MARTIN KUCHER, AUGSBURG (DE); NORBERT RICHTER, AUGSBURG (DE)

(73) Assignee: SGL CARBON SE, WIESBADEN (DE)

(21) Appl. No.: 13/684,693

(22) Filed: Nov. 26, 2012

Related U.S. Application Data
(63) Continuation of application No. PCT/EP2011/058558, filed on May 25, 2011.

(30) Foreign Application Priority Data
May 25, 2010 (DE) 10 2010 029 289.3

(51) Int. Cl. H05B 7/18; G01R 23/16

(52) U.S. Cl. CPC H05B 7/18; G01R 23/16
USPC 373/104; 324/76.21

(57) ABSTRACT

A method for operating an arc furnace, an oscillation measurement device for an arc electrode, and a configuration for the arc furnace are described. Using simple measures for operating the arc furnace, it is possible to carry out, in a particularly safe and productive manner, an oscillation measurement on the at least one arc electrode. On the basis of which the operation of the configuration for the arc furnace can be controlled with regard to the mechanical and/or electrical operating parameters.

### CROSS-REFERENCE TO RELATED APPLICATION

This application is a continuation, under 35 U.S.C. §120, of copending international application No. PCT/EP2011/058558, filed May 25, 2011, which designated the United States; this application also claims the priority, under 35 U.S.C. §119, of German patent application No. DE 10 2010 029 289.3, filed May 25, 2010; the prior applications are herewith incorporated by reference in their entireties.

### BACKGROUND OF THE INVENTION

### Field of the Invention

The present invention relates to a method for operating an arc furnace, an oscillation measurement device for an arc electrode and a configuration for an arc furnace.

In certain material processing or finishing processes, arc processes are used to introduce thermal energy into the material that is to be processed or finished. In this context, a current flow is generated between an arc electrode that is to be provided and the material or substance that is to be processed or finished and/or a counter electrode configuration to be provided correspondingly by controlled generation of an electrical voltage using an electric arc, that is to say without direct physical contact between the arc electrode on the one hand and the material or substance to be processed or finished and/or the counter electrode configuration on the other hand, but instead via an electrically conductive plasma between the arc electrode on the one hand and the substance and/or the counter electrode on the other hand that is created on the basis of the underlying atmosphere.

In operating processes of such kind, the arc electrodes exhibit signs of wear or even damage as a result of the high electrical and thermal loads. These signs of wear or damage in turn may result in the work process having to be interrupted and the system shut down, so that defective arc electrodes can be replaced, for example.

These interruptions to operations, as well as the physical effort of replacing defective electrodes are associated with commensurate costs. It would therefore be desirable if the signs of wear or damage could at least be detected in advance, during the earliest stages of such incidents, before the quality of the work process is seriously impaired or before an electrode fails, or if they could be delayed or even prevented by the selection of corresponding parameters.

Unfortunately, this has not been possible previously due to the harsh nature of the underlying operating environment and operating process, with its extreme thermal, mechanical and electrical loads.

### SUMMARY OF THE INVENTION

The object underlying the invention is to produce a method for operating an arc furnace, an oscillation measurement device for an arc electrode and a configuration for an arc furnace in or with which the method for operating an arc furnace may be arranged particularly safely and efficiently using simple measures.

The object underlying the invention is solved with a method for operating an arc furnace according to the invention having the features of the independent claims, with an oscillation measurement device for an arc electrode according to the invention having the features of the independent claims, and with a configuration for an arc furnace according to the invention having the features of the independent claims. Refinements are the object of the respective dependent claims.

According to a first aspect, the present invention provides a method for operating an arc furnace in which an electric arc is created and maintained between at least one arc electrode and a substance and/or a counter electrode by applying an electrical voltage to the at least one arc electrode to generate a current flow in controlled manner. In which method an oscillation measurement is carried out at the at least one arc electrode at least while the electric arc is maintained. In addition data characterizing an oscillation state of the at least one arc electrode and/or an operating state of the arc furnace are derived from the oscillation measurement, and the characterizing data is used to adjust and/or control the operation of the arc furnace. A central idea of the present invention thus consists in providing the capability to record the oscillation state of the provided one or more arc electrodes during an operational process for an arc furnace. On the basis of the oscillation measurement, data may then be obtained that describe or characterize the oscillation state and/or operating state of the arc furnace as a whole. The course of the subsequent operation of the arc furnace may then be planned on the basis of the characterizing data, for example by the appropriate selection and also adjustment of operating parameters or operating variables, whether they are geometric, mechanical and/or electrical in nature. It is also conceivable, for example, to adjust electrical voltages and/or current strengths, or also to adapt the electrode geometry according to the substance that is currently in the furnace vessel.

The oscillation measurement may be carried out without contact—particularly without direct or indirect mechanical contact with the at least one arc electrode. In a contactless oscillation measurement, the exceptional loads resulting from the high temperatures that are engendered during operation of an arc furnace may be reduced or avoided, so that disruptions to the measurements or even damage to the measurement instruments that must be used due to thermal, mechanical or electrical influences are eliminated.

The oscillation measurement may be carried out using optical devices and/or acoustic devices, particularly using ultrasound. In general, however, all other contactless measurement methods are conceivable, that is to say methods that may comprise oscillating movements of the arc electrode or the apparatuses connected therewith, without the need for direct mechanical contact.

Oscillation measurement may be carried out via an interference method and/or by exploiting the Doppler effect. Interference methods and/or Doppler methods are particularly accurate measuring methods, since with these methods even small deviations in the underlying base values result in measurement variables and changes thereof that are easily detectable both qualitatively and quantitatively.

With respect to the oscillation measurement, its evaluation and/or in the control and/or adjustment of the operation of the arc furnace, the characterizing data may be subjected to a Fourier analysis to detect states of resonance patterns and/or certain oscillation patterns of the at least one arc electrode and/or of the arc furnace, for example. Fourier analysis and other spectral methods are particularly suitable for examining oscillation states in systems, because they enable states of resonance or the like to be detected and evaluated with a particularly high degree of accuracy.

The oscillation measurement and evaluation thereof may serve as the basis for controlling or adjusting the mechanical and/or electrical operating variables of the arc furnace and/or the arc electrode as part of a control and/or adjustment procedure.

The method according to the invention and its embodiments may be used for processing and treating, finishing or melting a—particularly metallic—substance.

According to a further aspect of the present invention, an oscillation measurement device for an arc electrode is provided that is configured and equipped with measures for carrying out an oscillation measurement on at least one assigned arc electrode, particularly in an configuration for an arc furnace.

The oscillation measurement device may be configured for contactless oscillation measurement particularly without direct or indirect mechanical contact with the at least one assigned arc electrode.

The oscillation measurement device may be configured for oscillation measurement with optical and/or acoustic devices. It may include transmitting devices for transmitting certain optical and/or acoustic signals to the at least one assigned arc electrode and/or corresponding receiving devices for receiving optical and/or acoustic signals transmitted—particularly reflected—by the at least one assigned arc electrode. With the provision of corresponding transmitting devices and/or receiving devices, contactless measurement scenarios may be created particularly simply and yet reliably, regardless of whether such are based on electromagnetic phenomena, even in the optical field, or acoustic phenomena, for example including ultrasound or the like.

The oscillation measurement device may be configured to measure oscillations via an interference method and/or by making use of a Doppler effect. Interference methods and methods that exploit the Doppler affect both provide particularly high degrees of accuracy in measuring oscillations by virtue of their high resolution capability.

The oscillation measurement device may be configured to measure oscillations via direct or indirect mechanical contact with the at least one assigned arc electrode. In this case, it is equipped with an oscillation sensor, for example, to which an oscillation state or an associated effect of the at least one assigned arc electrode may be transmitted via the mechanical contact. In general, any oscillation sensors may be used. Piezosensors, inductive sensors or even optical gyros or the like are conceivable. In this context, multiple sensors may also be used in combination, so that oscillation movements may be resolved in the three spatial directions x, y and z and independently of one another, for example.

The oscillation sensor—and particularly a measurement circuit of the provided oscillation measurement device and connected to the oscillation sensor—may be configured as a measuring unit inside an insulating configuration. The provided measurement circuit may already be responsible for partially evaluating the primary data returned by the oscillation sensor, so that the data in partially evaluated form after preliminary processing may be stored, read out and/or transmitted. For this purpose, the measurement circuit may contain corresponding devices, such as corresponding control or calculation circuits, a memory and transmitting and receiving devices.

The insulating configuration may be configured to ensure thermal insulation/cooling and/or for mechanical coupling of its interior with the exterior. Given the thermal, electrical and mechanical loads mentioned in the preceding, corresponding insulation devices are advantageous for protecting the measurement mechanisms, in order to prevent measurement from being distorted or the measuring devices themselves from being damaged.

The insulating configuration may comprise a plurality of consecutively arranged, nested insulation containers, wherein at least the outermost insulation container in particular is directly or indirectly mechanically coupled with the at least one assigned arc electrode and the interior of the innermost insulation container houses the measuring unit and particularly the sensor and/or the measurement circuit.

Various numbers of individual nested insulating containers may be selected according to the actual or anticipated load. Accordingly the individual containers may be configured differently, and their contents or filler materials may differ. In this context, it must be ensured that the insulation is sufficient to prevent the temperature in the innermost zone, where the actual measurement unit with the sensor and the measuring circuit is located, from exceeding the maximum permissible operating temperature throughout the entire operating cycle, that is to say the entire period for which the measuring system is exposed to thermal input from the outside until the next break in operations, when the application of thermal input ceases.

One or more insulating containers may each have a wall area with the external limit and/or with the thermal insulation/cooling configuration.

The inside of one or more insulating containers may each be partly of completely filled with a thermal insulation and/or coolant filler material.

The wall zones form barriers with respect to thermal conduction and may also function as thermal radiation barriers due to their reflective properties. The insulating and/or cooling materials have the same functions, although in this case the emphasis is on preventing thermal conduction, unless particular material properties with regard to phase transitions are used. This will be described in greater detail hereinafter.

Each wall zone of a given insulating container may comprise one or more walls. The provision of a plurality of walls enables the thermal conductivity to be reduced due to the multiplicity of adjoining interface surfaces.

Each wall zone may be configured with or from multiple materials from the group of materials that include metal-containing materials, aluminum, steel, ceramic materials, sintered ceramic materials, plastics, fiber-reinforced materials and combinations thereof. Many different materials may be used. These are selected individually according to the positioning of the respective insulating container and the associated thermal, mechanical and electrical loads

Each wall zone and/or each wall—particularly on the respective outer side—may be partly or entirely configured with mirroring. The mirroring increases the reflective property with regard to thermal radiation.

Each insulating and/or cooling material may be constructed with or from one or more materials having low thermal conductivity, particularly in the range from less than about 3 W/m K, preferably in the range from less than about 0.3 W/m K.

Each insulating and/or cooling material may be constructed with or from one or more phase transition materials or phase change materials, particularly with a solid-liquid transition and/or a liquid-gas transition, preferably with a high phase change enthalpy or high phase transition enthalpy, particularly in the range from about 25 kJ/mol or higher. Besides preventing or lowering thermal conductivity or thermal radiation, precisely this effect may also be highly advantageous due to the absorption of latent heat. For example, if a phase transition from solid to liquid is intended, consequently the phase transition material or phase change material functions practically as a constant temperature mantle that lies on the phase change temperature of the underlying phase change material, and particularly until the phase transformation of the phase change material is completely finished, that is to say until—in the case cited here—the solid originally present has been converted entirely into a liquid. The same applies for a substance with a phase transition from the liquid to the gas phase.

Each insulating and/or cooling material may be constructed with or from one or more materials from the group of materials including water, zeolite materials, particularly zeolite granulate, perlite materials particularly perlite granulate, foam materials, particularly carbon foam materials, and combinations thereof. Particularly for external use—the use of water is highly advantageous. Thus for example, it is feasible to use the phase transition from liquid to gas-phase when using water. In this way, a cooling mantle may be provided for external use that attains a temperature of 100° C. as long as the water is in liquid form and does not exceed its boiling point. It must only be ensured that sufficient coolant water is present, which—converted into steam by the boiling process—may escape from the corresponding interior of the underlying insulating container.

Separating fins may be provided as additional insulating devices.

These may each brace the outer side of an inner insulating container against the inner side of a respective outer insulating container and/or brace an inner wall of a wall zone outwardly against a the inner side of an outer wall of the same wall zone.

The separating fins result in a minimal contact area or a minimal contact surface between the nested insulating containers, so that heat transfer even through thermal conduction is extremely low at these contact points with minimal surface area.

In order to transmit oscillations inwards from the outside, a portion of the wall zone of the outermost insulating container may be constructed from an oscillation transmitting element that extends into the interior of the outermost insulating container and is made with or from one or more materials with good sound conductivity or high sound velocity and low thermal conductivity, particularly in the form of a stone-like material, preferably made with or from granite and/or in the form of a slab. The advantage of a granite slab or similar consists in that such materials have particularly favorable mechanical properties, since they transmit oscillation states very effectively, for example sound in the subsonic range from a few hertz to the ultrasonic range of several tens of kilohertz, but at the same time possess very low thermal conductivity, compared with metals for example.

The oscillation transmitting element may be in direct mechanical contact with the wall zone of at least one insulating container positioned more inwardly.

It is also conceivable for the oscillation transmitting element to span the area of several insulating containers towards the interior, and thus penetrate multiple insulating containers at the wall zones thereof.

According to a further aspect of the present invention, a configuration for an arc furnace is also produced having a furnace vessel with at least one arc electrode, which is inserted or may be inserted into the furnace vessel, and with an oscillation measurement device for measuring oscillations at the at least one arc electrode. The central idea of the configuration for an arc furnace is thus the provision according to the invention of an oscillation measurement device for measuring the oscillation state of an arc electrode during operation thereof.

A plurality of arc electrodes may be configured with one common or with multiple, particularly a corresponding number of oscillation measurement devices, each assigned to a respective electrode. Since in general a plurality of arc electrodes may also be provided in a configuration for an arc furnace, it is also expedient to monitor the oscillation state of a plurality, for example all, arc electrodes. In principle this may be performed by a single oscillation measurement device, especially if this uses a contactless measuring method. However, under certain circumstances it may be advisable to use a corresponding number of individual oscillation measuring devices, each being assigned to an individual arc electrode.

The oscillation measuring devices may particularly be constructed in the manner according to the invention described.

A control device may be provided, by which data returned by the oscillation measuring device may be recorded and evaluated, by which the operation of the configuration for the arc furnace is controllable and/or adjustable—particularly with a feedback function—, wherein particularly a method according to the invention for operating and controlling an arc furnace may be practicable. The control device may record, store and process the raw data returned by the respective sensor, or record, store and process the measurement data that has already been processed by the provided measurement circuit, and may generate corresponding control signals and transmit such signals to the corresponding other devices of the configuration in order to adjust or control the operation appropriately.

The oscillation measuring device provided according to the invention may be:

attached directly or indirectly to an area that is—at least during operation—outside of the open vessel and/or the area or end of the arc electrode farthest from the furnace vessel,

configured for contactless measurement tapping directly or indirectly—at least during operation—outside of the open vessel and/or the area or end of the arc electrode farthest from the furnace vessel,

attached directly or indirectly to a holder for the arc electrode, particularly to an area of a cooling device for the holder,

configured for contactless measurement tapping directly or indirectly on a holder for the arc electrode, particularly on an area of a cooling device for the holder,

attached directly or indirectly to a conveyor dog or conveyor element of the arc electrode, and/or

configured for contactless measurement tapping directly or indirectly on a conveyor element of the arc electrode.

In general, all tapping points that allow access to the mechanical state of motion of the arc electrode are conceivable. However, the need for the most direct access possible to the oscillation state of the arc electrode must be weighed against the resilience of the oscillation measurement device with respect to the thermal, mechanical and electrical loads.

Other features which are considered as characteristic for the invention are set forth in the appended claims.

Although the invention is illustrated and described herein as embodied in a method for operating an arc furnace, an oscillation measurement device for an arc electrode and a configuration for an arc furnace, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a flow diagram of an embodiment of a method for operating an arc furnace according to the invention;

FIGS. 2A-5B are schematic block diagrams showing various embodiments of a configuration for the arc furnace according to the invention, the various configurations differ in respect of positioning of an oscillation measurement device and/or a design of the furnace as an open or closed vessel;

FIG. 6 is a block diagram showing details of a control and regulation circuit for another embodiment of the configuration for the arc furnace according to the invention;

FIG. 7 is a cutaway side view, showing possible positioning of the oscillation measurement device according to the invention in an area of an arc electrode and a support arm thereof;

FIG. 8A is cutaway plan view showing an embodiment of the oscillation measurement device according to the invention that functions on a basis of a mechanical contact; and

FIG. 8B is a cutaway side view showing the embodiment of the oscillation measurement device according to the invention that functions on the basis of the mechanical contact.

### DETAILED DESCRIPTION OF THE INVENTION

Embodiments of the present invention will be described in the following. All embodiments of the invention including their technical features and properties may be considered in isolation or assembled and combined with one another in any permutation and without limitation.

Features or elements that are structurally and/or functionally identical or similar or that have equivalent effects are designated in the following with the same reference signs with regard to the figures. A detailed description of such features or elements will not be repeated in every case.

The following text will deal with the drawings in general.

The present invention also relates particularly to means and methods for measuring electrode oscillations in a steelworks.

It is currently not possible to measure oscillations of electrodes or arc electrodes 220 during operation in a steelworks for example. However, in some steelworks, electrodes malfunctions occur inexplicably and the steelworks operator can do no more than suspect that the cause is possibly fatigue failure.

With the method for measuring and rapidly adjusting the oscillations of arc electrodes or electrodes 220 during operation suggested according to the invention, steps may be taken against failures of such kind. For this purpose, a new vibration measurement device 100, also referred to as oscillation measurement device 100, is suggested.

The oscillations of an arc electrode 220 are transmitted for example via a conveyor element 224 a conveyor dog 224 to the measurement box of oscillation measurement device 100. In the measurement box of oscillation measurement device 100, for example a granite slab 50, 50′ (coefficient of thermal conductivity 2.6 W/mK) transmits the oscillations to the actual measurement sensor 1 and the measurement electronics or circuit 2. The oscillations may be recorded via three acceleration sensors arranged in all three spatial axes and stored for example in an integrated data logger.

The option also exists to perform temperature measurement with an additional sensor, in order to compensate for any thermal influences.

With an add-on module, the oscillations and the temperature may be transmitted to a computer via a transmitter integrated in the box (Bluetooth, W-Lan . . . ) and evaluated online.

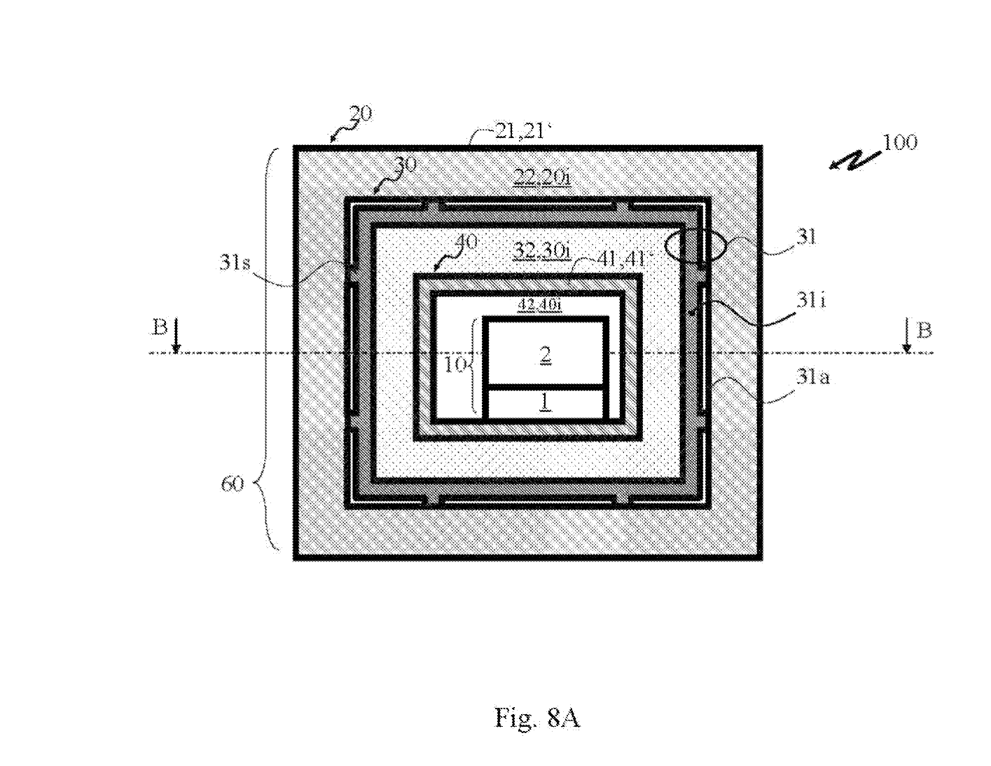

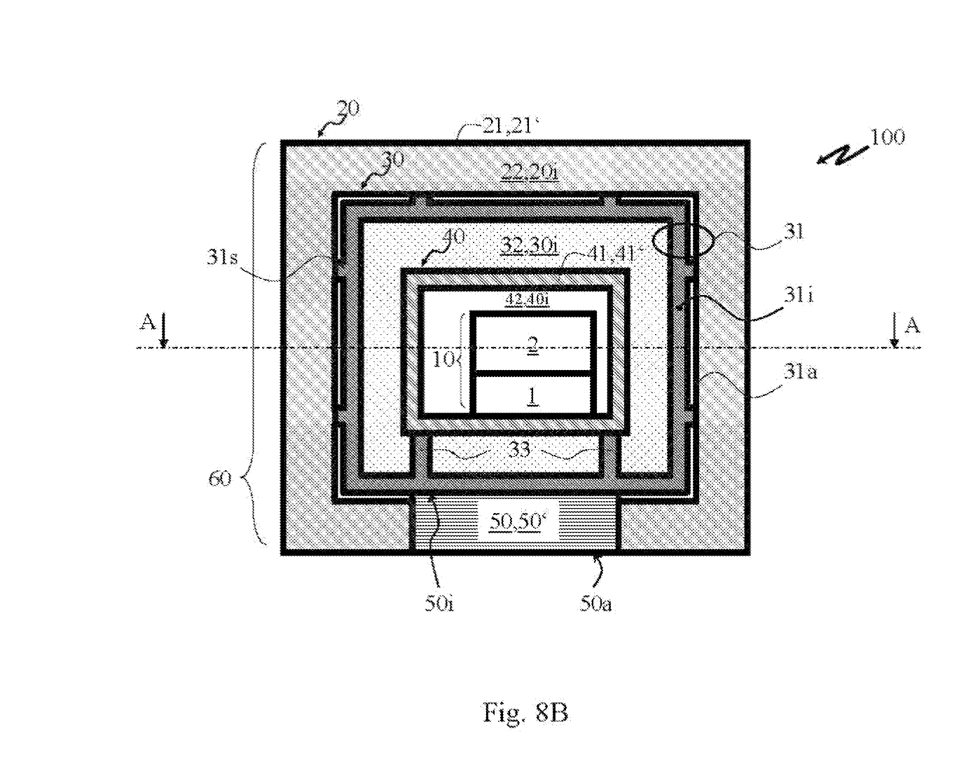

In FIG. 8A a sensor 1 and electronics assembly 2 may be isolated with a multi-stage concept. In all, for example, three boxes 20, 30, 40 are nested in each other as insulating containers 20, 30, 40.

An outermost box 20, made for example from a CFC substance or sheet steel as a wall 21, 21′, is filled for example with a water-saturated zeolite granulate as a filler 22. The outermost or first box 20 may also be insulated with an insulating substance other than filler 22, for example a carbon foam having a coefficient of thermal conductivity of 0.15 W/mK or a perlite granulate having a coefficient of thermal conductivity of 0.05 W/mK.

A second box 30, manufactured with a wall of aluminum or steel as an inner wall 311, is filled with water or another phase change material as a filler 32 and serves to stabilize the temperature in the chamber with a third box 40 at a low level, not above 100° C. for example. The material of the walls 21, 31, 41 and/or of the fillers 22, 32, 42 may be selected according to the application under consideration.

The outer casing 31a of the wall 31 of the second box 30 may be furnished with a reflective metal panel that reflects infrared radiation and thus reduces the thermal radiation to which the second box 30 is exposed.

In order to further reduce the transfer of heat from the panel 31a to the interior 30i of the second box 30, the panels 31a are attached to thin vanes 31s.

The third and innermost box 40 is for example impermeable to water and dust and contains the actual sensor equipment 1 and the measurement electronics 2. In order to inhibit or reduce the transmission of heat due to thermal conduction and/or thermal radiation, this too is arranged in such manner that the thermal flow is only transported via for example four small vanes 33.

The drawings will now be discussed in detail.

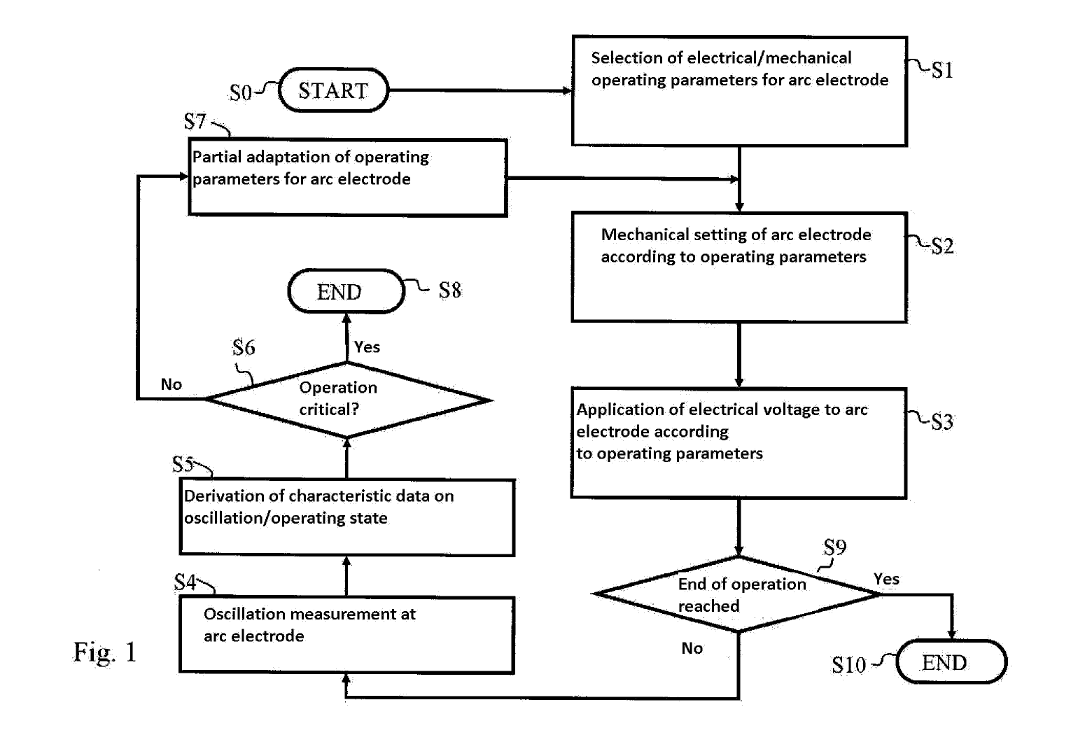

FIG. 1 shows a block diagram of an embodiment of the method according to the invention for operating an arc furnace 200, 210′.

In a step S0—referred to as the start phase—preparations are made for operating an arc furnace 200′, 210′. Thus, a furnace vessel 210 under consideration (see following description) is charged accordingly. Then, the arc electrode 220 under consideration is positioned in the area inside vessel 210, possibly with the inclusion of vessel cover 212.

Then, in first operating step S1 all of the appropriate operating parameters for arc electrode 220 and arc furnace 200′, 210′ are selected, applies to the electrical parameters as well as the mechanical parameters, that is to say the configuration and geometry of the electrode 220 in the interior of furnace vessel 210, selection of the atmosphere and the other components of the substance 300 to be treated, as well as the mode in which electrical voltage is to be applied to arc electrode 220.

In step S2, the arc electrode 220 under consideration is adjusted mechanically according to the selected operating parameters.

In step S3, the configured arc electrode 220 is then energized with electrical voltage according to the selected operating parameters. The electrical voltage is generated between the arc electrode 220, or the plurality of arc electrodes 220 as applicable, and the substance 300 to be treated and/or a provided counter electrode 211′ in lower area 211 of the arc furnace 210.

Steps S2 and S3 are generally carried out continuously and simultaneously with one another during ongoing operation. This means that in continuous operation—uninterrupted as far as possible—the arc electrode 220 or a plurality thereof are charged with electrical voltage according to the currently determined operating parameters, and are reflected simultaneously in the configuration 200 for the arc furnace 200′, 210′ according to the mechanical and geometric operating parameters.

In step S9 between steps S3 and S4, a test may be carried out to determine for example whether operation has ended normally, for example whether a normal end criterion has been satisfied or is present.

If this is the case, for example because the substance 300 has been completely melted in a melting operation, the process may proceed to final step S10 in order to make the necessary preparations for terminating the operation of the configuration 200 for the arc furnace 200′, 210′. Therefore tapping is carried out if applicable, or the treated or processed substance 300 is drawn off in some other way, in particular after the electrical power has been removed from the configuration 200, meaning in particular that the arc furnace 210 and the electrode 220 are earthed and that a potential difference no longer exists between them.

At this point, it is provided according to the invention that, if a criterion for a normal end of operations is not found in step S9, for example because in the example of a melting operation given the above substance 300 has not yet melted completely, the furnace 200′, 210′ must continue running and in general process steps S4 to S7 must be executed, which then return to primary process steps S2 and S3.

Accordingly, in step S4 the oscillation measurement is carried out at the arc electrode 220 or the plurality of arc electrodes 220.

In step S5, characteristic data is derived from the data obtained in oscillation measurement S4 and is used to characterize the operating state and/or oscillation state of arc electrode 200 as such, or also of the entire configuration 200 of the arc furnace 200′, 210′.

This is followed by an interrogation step S6, in which a check is made as to whether the operation of the system or configuration 200 is critical, that is to say whether operation can no longer be executed normally by adjustment and control, in particular whether an existing or developing oscillation state of the system or configuration 200 and particularly of the arc electrode 220 is no longer manageable. This may be the case in particular if the operating state of the arc furnace 200′, 210′ can no longer be adjusted and fatigue failure of the arc electrode 220 or arc electrodes 220 is imminent.

Accordingly, if the operation is evaluated as critical, for example because an oscillation state of the system or configuration 200 and particularly of the arc electrode 220 proves to be unmanageable, an abnormal termination to final step S8 takes place.

Otherwise—for example if oscillations of the arc electrode 220 or arc electrodes 220 are moving in a non-critical range, are manageable and do not have to be reduced or only minimally reduced by adapting the operating parameters—regular operation is resumed from step S7.

In this step S7, the derived data, and particularly the data characterizing the oscillation state and/or operating state, is used to adapt the operating parameters or operating variables for the operation of the arc electrode 220 and the configuration 200 for the arc furnace 200′, 210′ as such.

In this step, various procedures may be envisaged. For example, previously prepared operating parameter tables may be present and read out on the basis of the characteristic data for the oscillation state and operating state.

Following appropriate adaptation S7 of the operating parameters, the mechanical-geometric settings for the arc electrode 220 and the configuration 200 are made in their entirety, and the electrical variables necessary for operation are controlled and adjusted accordingly in the following steps S2 and S3.

In this context, it should be noted again that all steps S2 to S7 are carried out in parallel and continuously, that is to say the measurements are taken and evaluated constantly, particularly while the arc electrode 220 is being charged in step S3, that is to say during ongoing operation, and that the geometric and mechanical variables and the electrical operating values are also being adapted constantly and continuously on the basis of the evaluation data, and usually without the need to interrupt operations.

Thus according to the invention it is possible to detect critical states for the operation of the arc electrode 220 on the basis of the characteristic data derived in steps S5 and S7, so that the mechanical, geometric and electrical operating variable for the arc electrode 220 may be set such that the critical operating state for the arc electrode 220 may be exited and continued safe operation is possible.

In this way, the wear on the arc electrode 220 and the assembly 200 as a whole, and damage thereto in general is reduced or even prevented, thus resulting in longer uninterrupted operation and prolonged service life of the components of configuration 200 and particularly of arc electrode 220.

The productivity of the configuration 200 of such kind may be increased overall compared with conventional configurations without oscillation measurement.

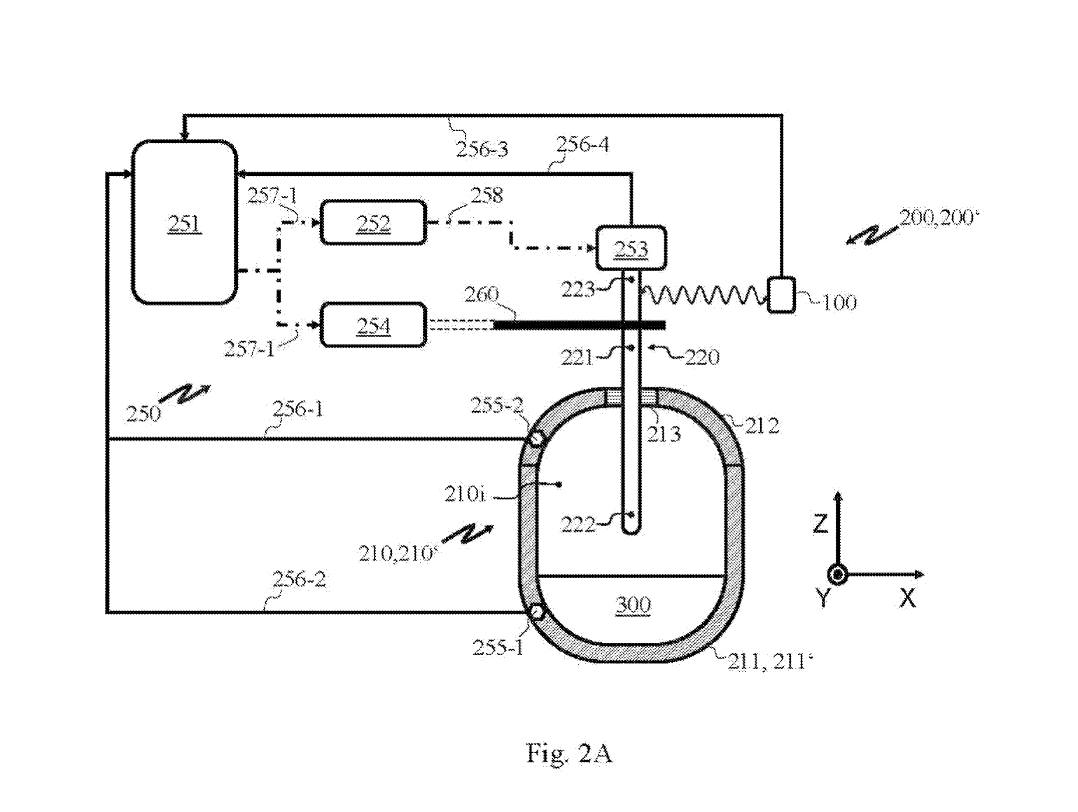

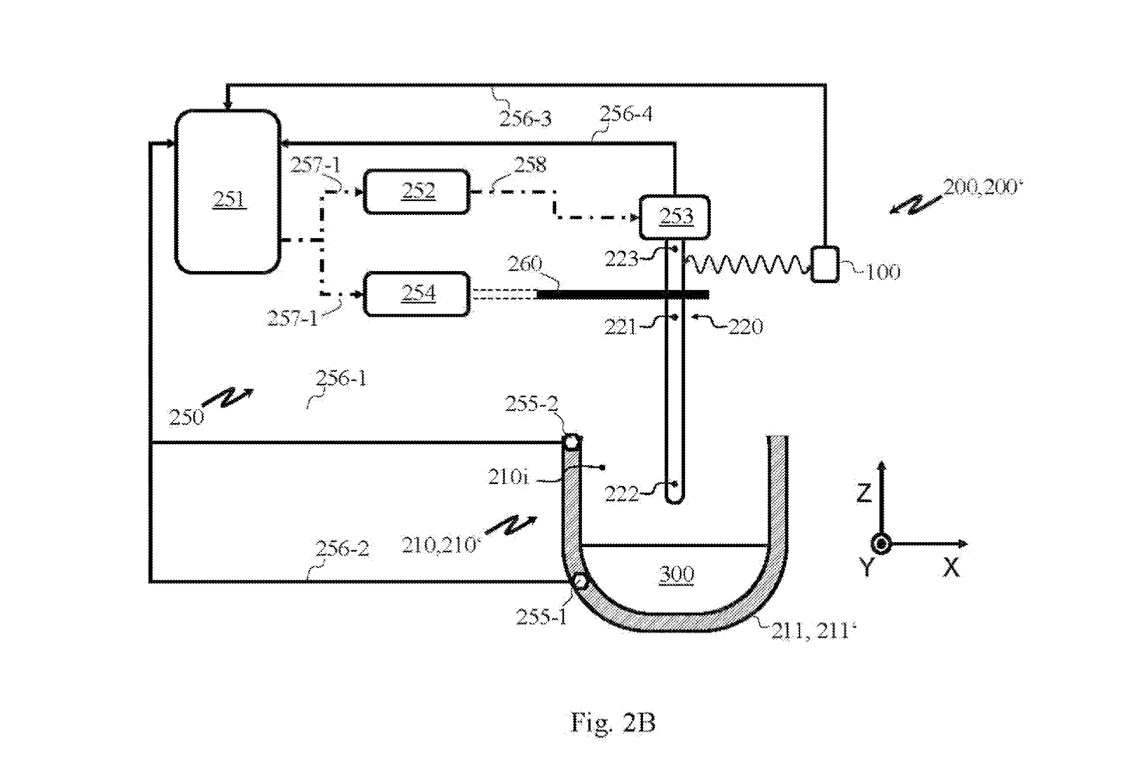

FIG. 2A shows a first embodiment of the configuration 200 according to the invention for the arc furnace 210, 210′ in the form or a schematic type block diagram.

The core component of the configuration 200 is the actual arc furnace 200′, 210′. This contains a furnace vessel 210. The vessel has a vessel lower part 211, and in the configuration of FIG. 2A a cover or closure 212. A pass-through and sealing area 213, through which the arc electrode 220 on which configuration 200 is based protrudes into the arc furnace 210, is conformed in the upper area of the cover or closure 212.

The arc electrode 220 itself contains a body 221 in the form of a rod 221 with a leading or arc end 222, which protrudes into the interior 210i of the arc furnace 210, against which the opposite, second end 223 of rod 221, which is farthest from the arc furnace 210, is retained by a support arm 260 or holder 260. The support arm 260 also allows a corresponding adjustment of the rod 221 of the arc electrode 220, so that a corresponding distance may be established between the substance 300 located in the interior 210i of the arc furnace 210, which is to undergo processing or treatment, and the arc end 222 of the arc electrode 220, by positioning with the aid of the support arm 260, for example by raising and lowering the support arm 260 in direction Z.

A counter electrode configuration 211′ is optionally provided correspondingly in the vessel lower area 211, and which is highly suitable for creating the electrical potential difference between the arc end 222 of the rod 221 on the one hand and the arc electrode 220, and particularly the substance 300 to be treated on the other. Measuring sensors 255-1 and 255-2 are also provided in furnace vessel 210 to record measurement data for controlling the operation of configuration 200.

A control area 253 or operating unit 253 for the arc electrode 220 is also configured in the area of the second end 223 of the arc electrode 220, which is farthest from the arc furnace vessel 210. In the embodiment shown here, the control area 253 serves both as an electrical connection point and thus for applying the electrical voltage by introducing electrical charges via line 258 from electrode driver 252, and also for outputting certain measurement variables via line 256-4, for example for outputting the values of the electrical voltage actually applied or of the electrical current actually flowing as actual values.

In the configuration 200 shown in FIG. 2A, the arc electrode is controlled via an end 223 of the arc electrode 220 farthest from the arc furnace, and is thus controlled separately from the support arm 260 and the controller or operating unit 254 therefor. In practice however, electrical voltage is usually applied to the arc electrode 220 via the support arm 260 and not via the end 223 farthest from the furnace vessel. In this case, the electrode driver 252 accesses the support arm 260 directly via a corresponding interface. The supports 252 and 254 may for example be integrated in a single unit, which carries out and controls both positioning and energizing with electrical voltage.

The oscillation measurement device 100 also connects with the second end 223 of the arc electrode 220, which end is farthest from the furnace vessel 210, in order to determine the oscillation state of the arc electrode 220 on the basis of corresponding oscillation measurement data. The raw data and/or also correspondingly pre-evaluated, preprocessed data are collected via line 256-3.

All collected data is recorded in the evaluation and control unit 251, via lines or measurement lines 256-1 and 256-2 with regard to the additional sensors 255-1 and 255-2 arranged in furnace vessel 210, via measurement line 256-3 for the oscillation measurement device 100 provided according to the invention, and via measurement line 256-4 for the operating unit 253 of the arc electrode 220.

On the basis of the evaluation in the evaluation and control unit 251, corresponding control signals are then transmitted via control lines 257-1 and 257-2 to driver device 254 for the electrode and the driver device 254 for the support arm 260, so that the mechanical, geometric and electrical operating variables may be controlled or adjusted for operating the configuration 200 for the arc furnace 200, 210′ in accordance with the control data.

Consequently, the evaluation and control unit 251, the two drivers 252 and 254 and the operating unit 253 for the arc electrode 220 constitute the actual control 250 for operating the configuration 200 for arc furnace 200′, 210′ via the corresponding measurement lines 256-1 to 256-4 and control lines 257-1, 257-2 and 258 in cooperation with the oscillation measurement device 100 according to the invention and the additional sensors 255-1, 255-2.

The central idea in the configuration of FIG. 2A is the contactless measurement of the oscillation state of the arc electrode 220 by oscillation measurement device 100, shown here by the wavy line that is intended to represent the sending and receipt of a light signal or ultrasonic signal or similar. Due to the contactless measurement method, the mechanical, electrical and thermal loads to which the oscillation measurement device 100 according to the invention is exposed are relatively lower, even during under very severe operating conditions.

The configuration of FIG. 2B is essentially the same as the configuration of FIG. 2A, but in this case the furnace vessel 210 is open, and thus unlike the configuration of FIG. 2A has no cover are 212 and also no seal 213.

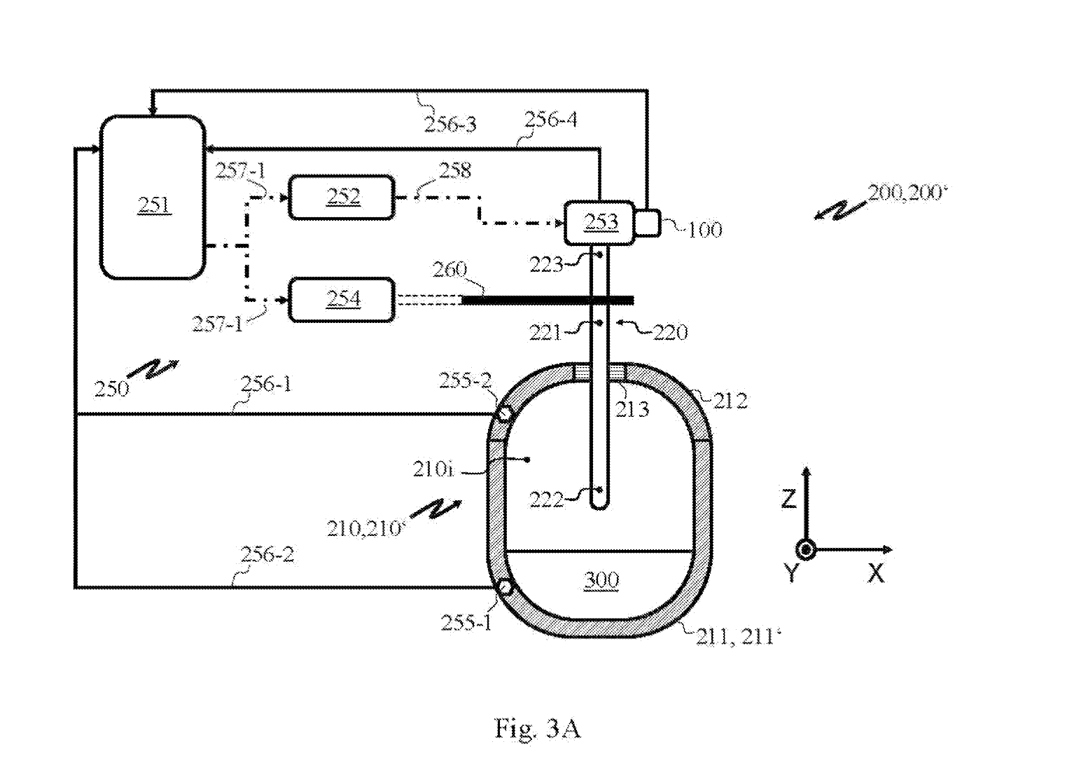

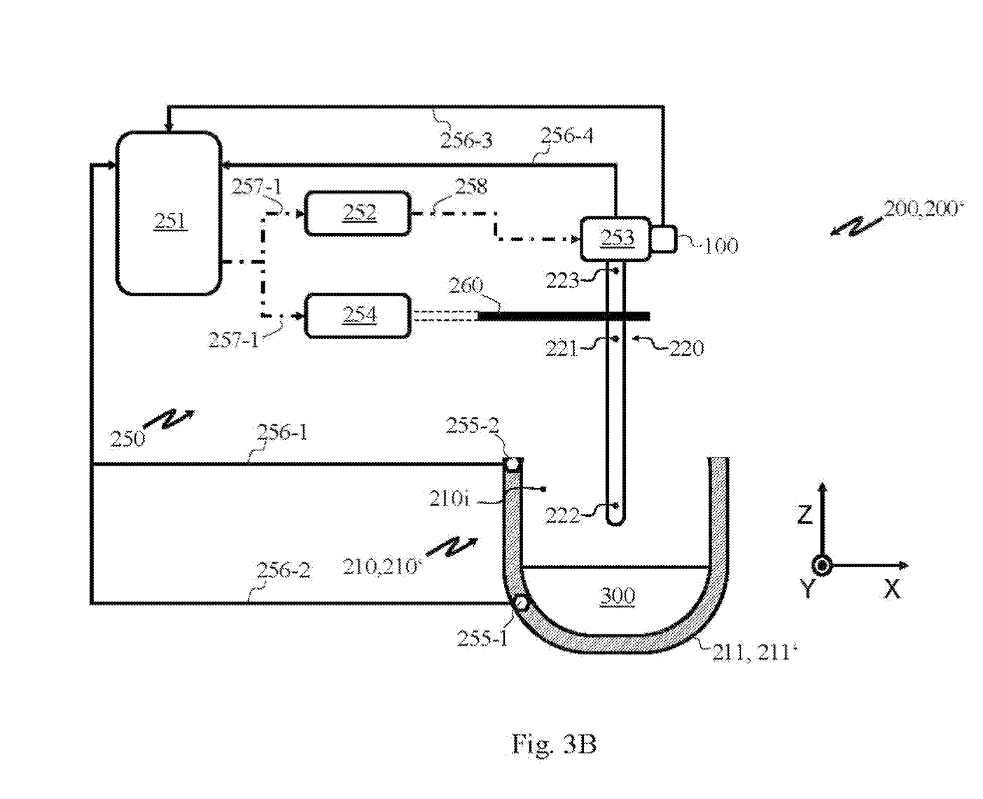

The configuration of FIG. 3A is essentially the same as the configuration of FIG. 2A with a closed furnace vessel 210, although in this case indirect contact is established between the oscillation measurement device 100 according to the invention and the arc electrode 220, via the operating unit 253, which during operation is entrained into a similar oscillating state to that of the arc electrode 220 itself due to the direct mechanical contact with arc electrode 220.

The configuration of FIG. 3B shows a similar situation to the configuration of FIG. 3A, but again with an open furnace vessel 210, without cover 212 or seal 213.

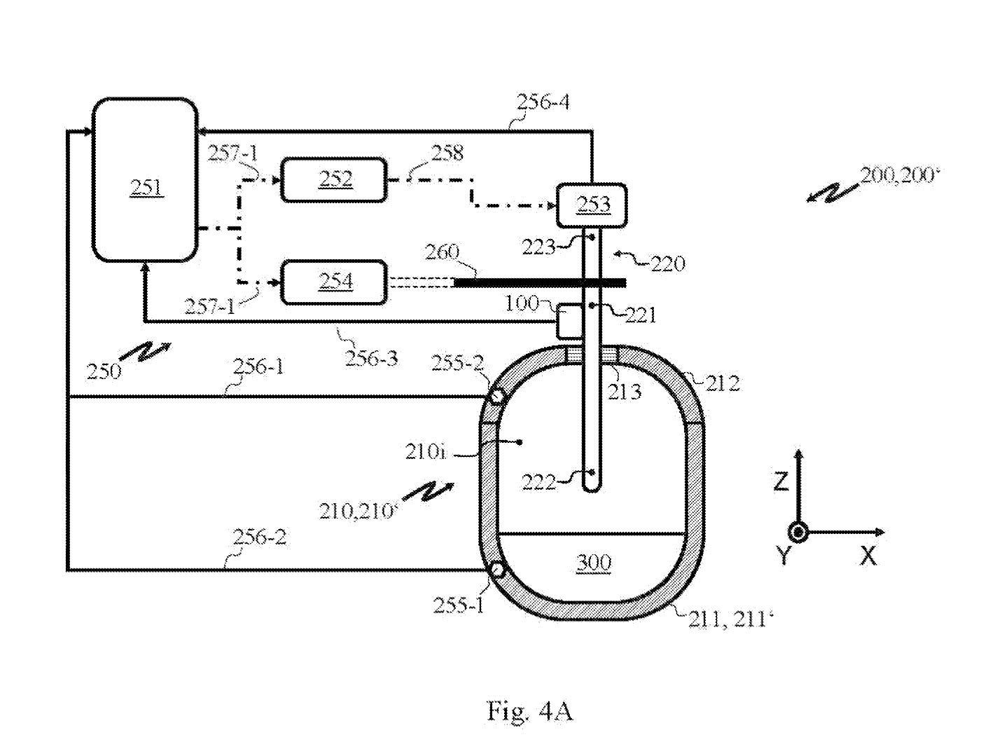

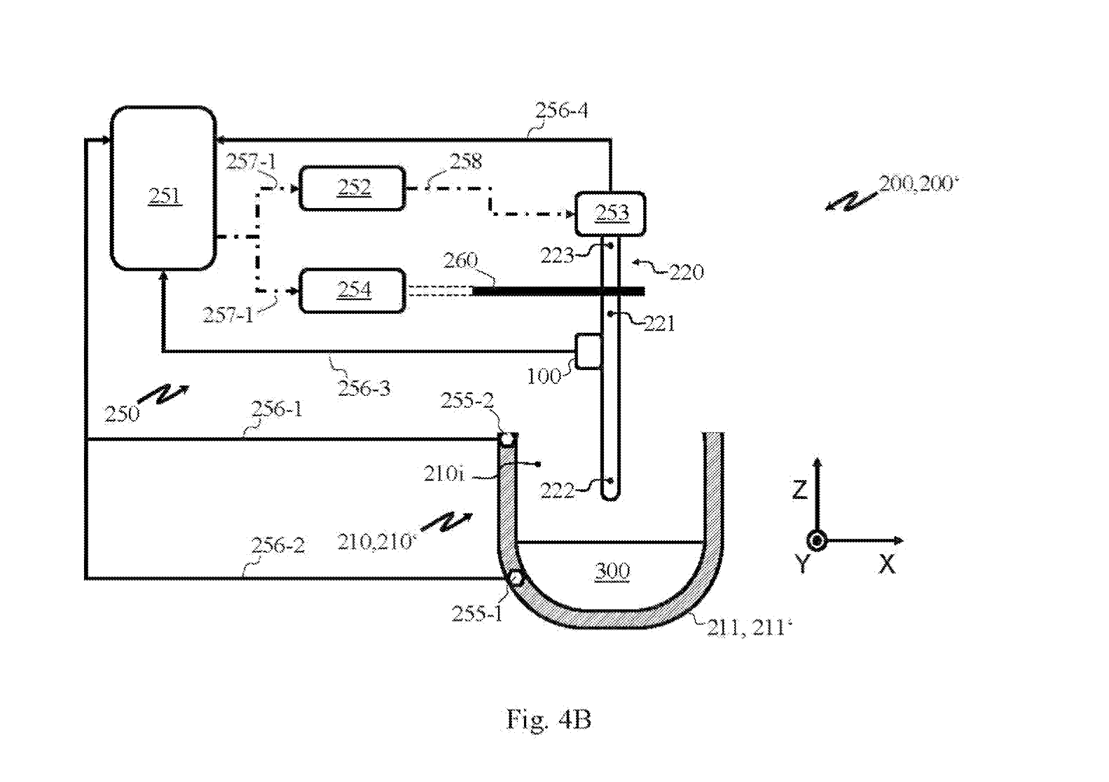

In the configurations of FIGS. 4A and 4B, in both the open and closed versions of the furnace vessel 210 the oscillation measurement device 100 provided according to the invention is located directly on the surface of rod 221 of the arc electrode 220, in this case directly below the support arm 260. This enables the oscillation state of arc electrode 220 to be measured very directly and very accurately.

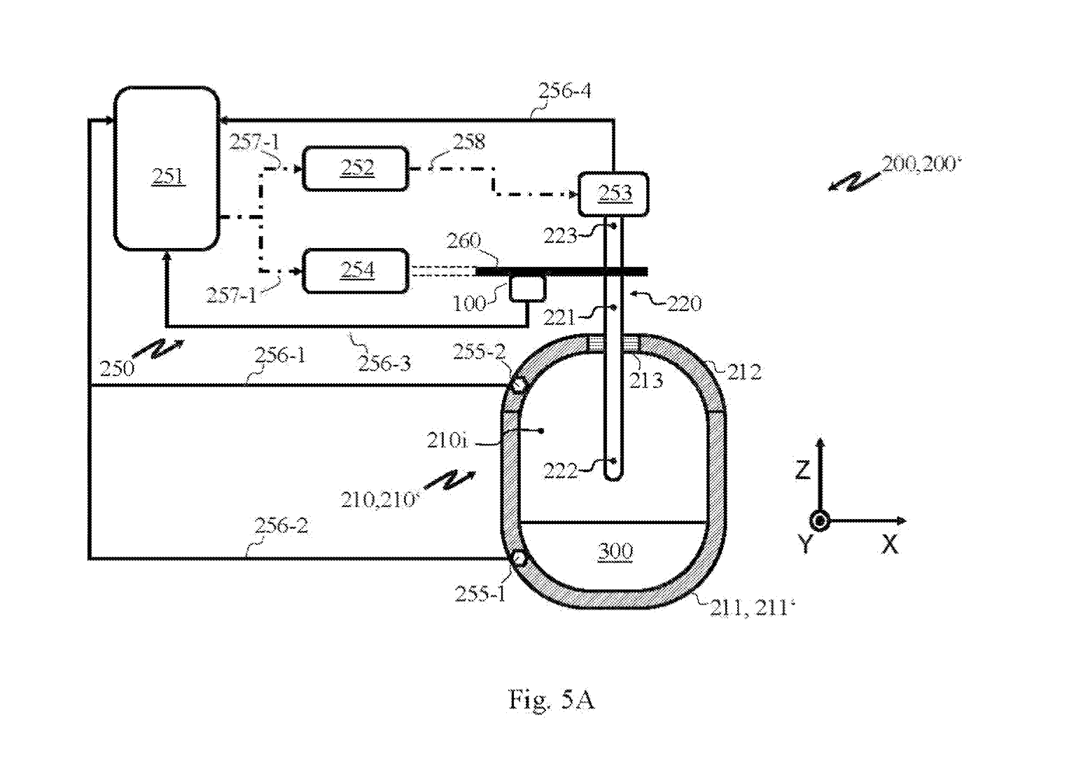

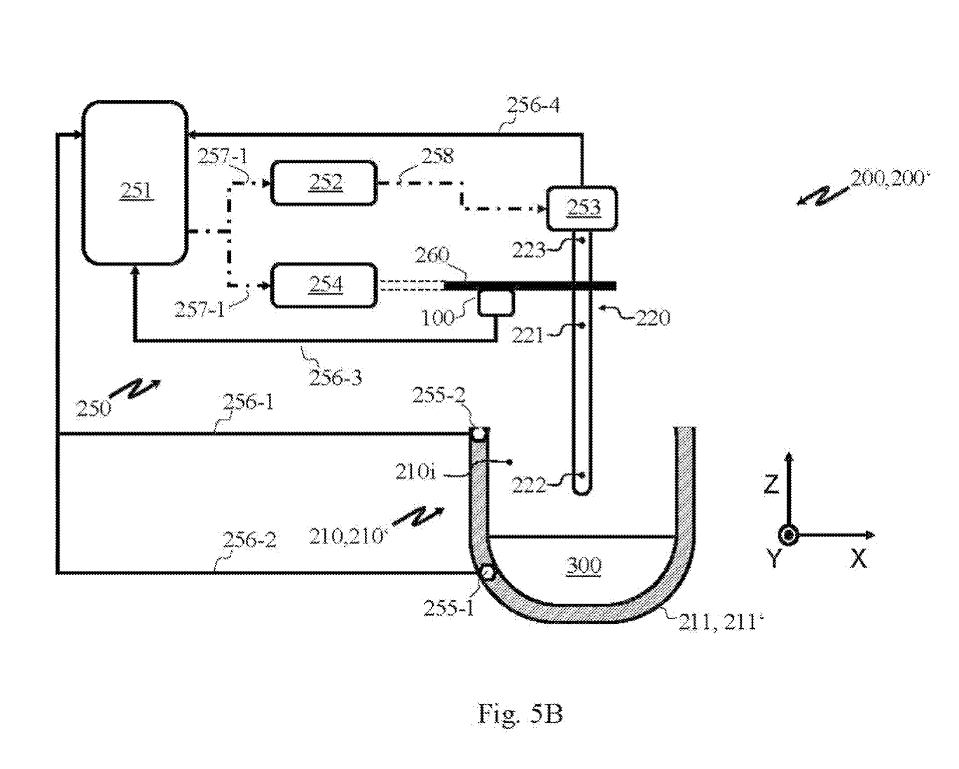

In contrast to the above, in the configurations of FIGS. 5A and 5B the oscillation measurement device 100 provided according to the invention is again located on the support arm 260 for the rod 221 of the arc electrode 220 for both open and closed versions of the furnace vessel 210. Because of the very close mechanical contact, specifically the support function of the support arm 260, this configuration makes it possible to reduce the mechanical, thermal and electrical loads yet still determine the oscillation state of arc electrode 220 extremely accurately via the oscillation state of the support arm 260.

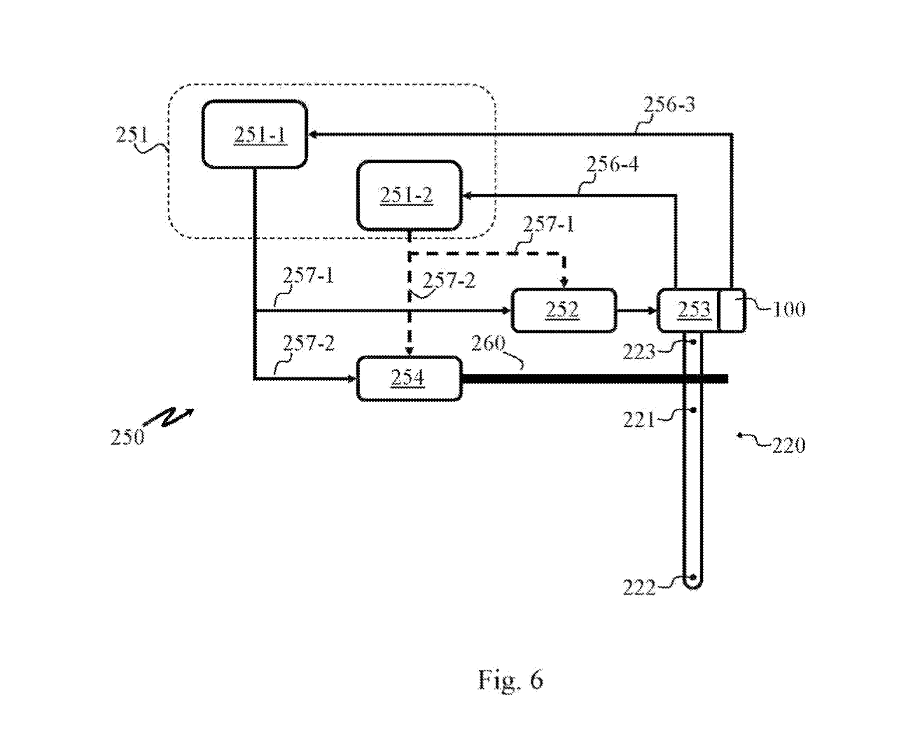

FIG. 6 again shows details of the controller 250 in relation to the oscillation measurement device 100 provided according to the invention for the arc electrode 220.

Here too, the arc electrode 220 is essentially in the form of a rod 221, with one end 222 closest to the furnace vessel, not shown here, and one end 223 farthest from the furnace vessel, not shown here, wherein the operating unit 253 for the arc electrode 220 is located on the farthest end to provide electrical connection and to transmit measurement data, for example relating to temperature, electrical parameters and oscillation data.

In the configuration shown in FIG. 6, the oscillation measurement device 100 according to the invention is integrated in the operating unit 253. In this embodiment, the evaluation and control 250, 251 are realized separately, by the provision of evaluation and control 251-1 of the data originating from the oscillation measurement device 100 and the evaluation and control 251-2 of the electrical operating parameters that are derived via the measurement line 256-4. The driver 254 for the support arm 260 and the driver 252 for the operating unit 253 of the arc electrode 220 are then supplied with corresponding control signals on the basis of the evaluation and control by the control subunits 251-1 and 251-2, via lines 257, 257-1, 257-2 and 258.

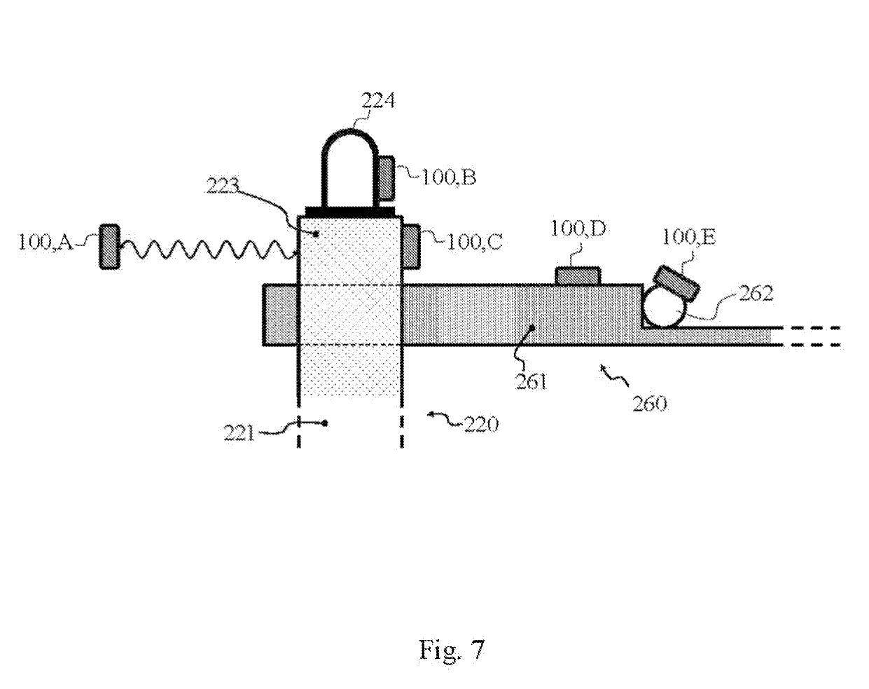

FIG. 7 is a schematic, cutaway side view of various configuration options A-E for the oscillation measurement device 100 according to the invention in conjunction with the arc electrode 220 configured in the form of the rod 221. All of these configuration options are realized in the area of the second end 223 of rod 221, which is located farthest from the furnace vessel 210, which is not shown here.

In position A, the oscillation measurement device 100 according to the invention is not in direct mechanical contact with the end 223 of the arc electrode 220, but rather makes use of a contactless measuring method, for example via electromagnetic waves or sound.

In position B, the oscillation measurement device 100 according to the invention is contacted directly by a conveyor element 224, a conveyor dog 224 or a conveyor hook 224.

In position C, the oscillation measurement device 100 according to the invention is attached directly to the surface of the arc electrode 220.

In position D, the oscillation measurement device 100 according to the invention is arranged on the surface of the support arm 260.

The support arm 260 and the ancillary components 261 thereof are often cooled by the provision of a cooling device 262. In this context, since the cooling device 262 is closely connected to the ancillary components 261 of the support arm 260, the oscillation measurement device 100 according to the invention may also be arranged in the same way as in position E, that is to say in direct contact with the cooling device 262. The cooling device 262 is for example a pipe that transports a coolant substance or similar.

FIGS. 8A and 8B show cutaway top and side views respectively of an embodiment of the oscillation measurement device 100 according to the invention for the arc electrode 220 that might be used in the context of positions B to E of FIG. 7.

The embodiment shown in FIGS. 8A and 8B of the oscillation measurement device 100 according to the invention has a three-stage insulating system or a three-stage insulating configuration in respect thermal and electrical influences. The three-stage insulating system 60 is formed by three nested insulating containers 20, 30 and 40. An outermost insulating container 20 has a single wall 21′, made for example from a CFC material or a steel sheet as wall zone 21. An interior 20i of the outermost insulating container 20 contains an insulating material 22, for example water-saturated zeolite granulate. Additionally, a further insulating substance—not shown explicitly here—, for example a carbon foam or a perlite granulate or the like, might also be applied to an inner side of wall 21 as interior cladding.

A second insulating container 30 is then located in the center of the outermost insulating container 20. A wall zone 31 thereof consists of an inner wall 311, made for example from aluminum or steel, and a mirrored outer casing 31a, against which the inner wall 311 is braced via spacer areas or spacer vanes 31s that have a small cross sectional area, in order to keep heat transfer through thermal conduction to a minimum.

A phase transition material or phase change material is provided in the interior 30i of the second insulating container 30 as an insulating material 32. This may be water, for example. Water not only has low thermal conductivity but also a comparatively low phase transition temperature with relatively high phase transition enthalpy for the transition from the liquid to the gaseous state.

Also in the interior 30i of second insulating container 30, a watertight and dust-impermeable box 40 is also located as an innermost insulating container 40, a wall zone 41 of which has a single wall 41′, and the interior of which contains, besides an optional filler 42, the actual measuring unit 10 consisting of the sensor 1 and the measurement and evaluation circuit 2. The innermost insulating container 40 is braced from below via vanes 33 that form part of wall zone 31 of second insulating container 30.

In order to improve the transmission of oscillations and still avoid the transfer of heat by thermal conduction, according to FIG. 8B the oscillation measurement device 100 according to the invention is furnished with an oscillation transmission element 50 in the form of a granite slab 50′ or the like. An external side 50a, external surface 50a or surface 50a of the granite slab 50′ is outwardly flush with the outer side of wall 21 of the outermost insulation container 20. As the oscillation transmission element 50, the granite slab 50′ passes completely through the wall zone 21 and the filler 22 of the outermost insulating container 20 and contacts the inner wall 311 of the wall zone 31 of the second insulating container 30, so that the sum of the mechanical oscillations are transmitted from the outside through external surface 50a of the granite slab 50′ to the inner wall 311 of the second insulating container 30 and from this through the vanes 33 to the innermost insulating container 40, where they are transmitted to the interior 40i thereof and oscillation sensor 1 by mechanical coupling. At the same time, only little heat is conducted through granite slab 50, vanes 33 and wall 41.

### REFERENCE SIGN LIST

1 Sensor, measuring sensor, oscillation sensor
2 Measurement circuit, evaluation circuit, measurement electronics, evaluation electronics
10 Measuring unit
20 Insulating container, first insulating container, outermost insulating container, box
20i Interior
21 Wall zone
21′ Wall
22 Insulating material, coolant material, filler
30 Insulating container, second insulating container, box
30i Interior
31 Wall zone
31i Inner wall
31a Outer wall, mirroring
31s Vane
31z Interspace
32 Insulating material, coolant material, filler
33 Vane
40 Insulating container, third insulating container, innermost insulating container, box
40i Interior
41 Wall zone
41′ Wall
42 Insulating material, coolant material, filler
50 Oscillation transmission element, granite slab
50a Outside, surface
50i Inside, inner surface
60 Insulation configuration, insulation system
100 Oscillation measurement device
200 Configuration, arc furnace configuration
200′ Arc furnace
210 Furnace vessel
210′ Arc furnace
210i Interior
211 Lower section, lower vessel area, vessel lower part
211′ Counter electrode configuration, counter electrode
212 Upper vessel portion, closure, lid, cover
213 Seal, sealing area, passthrough, passthrough area
220 Arc electrode
221 Material or body of arc electrode 220, rod
222 First end, end closest to furnace vessel 210, electric arc end
223 Second end, end farthest from furnace vessel 210
224 Conveyor element, conveyor dog, conveyor hook, suspension means
250 Controller, control device
251 Evaluation device or unit, control device or unit
251-1 Control subunit
251-2 Control subunit
252 Driver or driver unit of arc electrode 220, electrode driver
253 Control area or operating unit for arc electrode 220
254 Driver for support arm 260 of arc electrode 220
255-1 Sensor, measuring sensor
255-2 Sensor, measuring sensor
256-1 Measurement line
256-2 Measurement line
256-3 Measurement line
256-4 Measurement line
257-1 Control line
257-2 Control line
258 Control line
260 Support, holder, support arm
261 Support arm ancillary components 260
262 Cooling system for support arm 260
A Position for oscillation measurement device 100
B Position for oscillation measurement device 100
C Position for oscillation measurement device 100
D Position for oscillation measurement device 100
E Position for oscillation measurement device 100

1. A method for operating an arc furnace in which an electric arc is formed and maintained between at least one arc electrode and at least one of a substance or a counter electrode configuration by applying an electrical voltage to the arc electrode to generate an electrical current flow in a controlled manner, which comprises the steps of:
carrying out an oscillation measurement on the arc electrode at least while the electric arc is maintained;
deriving at least one of an oscillation state of the arc electrode or characterizing data of an operating state of the arc furnace from the oscillation measurement; and
using the characterizing data to at least one of adjust or control an operation of the arc furnace.

2. The method according to claim 1, which further comprises carrying out the oscillation measurement in a contactless manner without direct or indirect mechanical contact with the arc electrode.

3. The method according to claim 1, which further comprises carrying out the oscillation measurement by at least one of optical means, acoustic means, and ultrasound.

4. The method according to claim 1, which further comprises carrying out the oscillation measurement via at least one of an interference method or by exploiting a Doppler affect.

5. The method according to claim 1, which further comprises performing a Fourier analysis on the characterizing data during at least one of the oscillation measurement, during an evaluation of the characterizing data, or during a control and/or adjustment of the operation of the arc furnace, in order to detect states of at least one of resonance patterns or of certain oscillation patterns of the at least one of the arc electrode or the arc furnace.

6. The method according to claim 1, which further comprises controlling or adjusting at least one of mechanical operating variables of the arc furnace, electrical operating variables of the arc furnace, mechanical operating variables of the arc electrode or electrical operating variables of the arc electrode on a basis of at least one of the oscillation measurement, an evaluation of the characterizing data, or a control and/or adjustment.

7. The method according to claim 1, wherein the method is used to process, treat, finish or melt a substance including metallic substances.

8. An oscillation measurement device for an arc electrode, the oscillation measurement device comprising:
means for carrying out an oscillation measurement on at least one assigned arc electrode.

9. The oscillation measurement device according to claim 8, wherein the oscillation measurement device is configured for performing a contactless oscillation measurement without direct or indirect mechanical contact with the assigned arc electrode.

10. The oscillation measurement device according to claim 8, wherein the oscillation measurement device is configured for performing the oscillation measurement by at least one of optical means or acoustic means, the oscillation measurement device further comprising at least one of:
corresponding transmitting devices for transmitting at least one of optical signals or acoustic signals to the assigned arc electrode; or
corresponding receiving devices for receiving at least one of the optical signals or the acoustic signals, including reflected signals, transmitted by the assigned arc electrode.

11. The oscillation measurement device according to claim 8, wherein the oscillation measurement device is configured to carry out the oscillation measurement via one of an interference method or by exploiting a Doppler effect.

12. The oscillation measurement device according to claim 8, wherein the oscillation measurement device is configured to carry out the oscillation measurement via a direct or indirect mechanical contact with the assigned arc electrode, the oscillation measurement device further comprising:
an oscillation sensor to which an oscillation state of the assigned arc electrode or an effect thereof is transmittable via mechanical contact.

13. The oscillation measurement device according to claim 12, further comprising:
an insulating configuration having an interior; and
a measurement circuit, said oscillation sensor connected to said measurement circuit and together constructed as a measurement unit disposed in said interior of said insulating configuration.

14. The oscillation measurement device according to claim 13, wherein said insulating configuration configured for at least one of assuring thermal insulation/cooling or mechanical coupling between said interior of said insulating configuration and an outside environment.

15. The oscillation measurement device according to claim 14, wherein said insulating configuration contains a plurality of consecutively disposed, nested insulating containers including an outermost container and an innermost container, said outermost container is directly or indirectly coupled to the assigned arc electrode, and said innermost container having an interior and houses at least one of said measuring unit, said sensor or said measurement circuit in said interior of said innermost insulating container.

16. The oscillation measurement device according to claim 15, wherein:
at least one of said insulating containers has a wall zone for at least one of outward delimitation or thermal insulation/cooling, at least one of said insulating containers defining an interior; and
at least one of said insulating containers has at least one of a thermal insulation or coolant material in a form of a partial or complete filler disposed in said interior of said insulating container.

17. The oscillation measurement device according to claim 16, wherein each said wall zone of a respective said insulating container has at least one wall.

18. The oscillation measurement device according to claim 17, wherein said wall of each said insulating container constructed with or from at least one material selected from the group of consisting of metallic materials, aluminum, steel, ceramic materials, sintered ceramic materials, plastics, fiber-reinforced materials and combinations thereof.

19. The oscillation measurement device according to 17, wherein at least one of each said wall zone or a respective said wall is designed with at least one of partial mirroring or complete mirroring.

20. The oscillation measurement device according to claim 16, wherein at least one of said thermal insulating or said cooling material is made from or with at least one material having low thermal conductivity.

21. The oscillation measurement device according to claim 16, wherein at least one of said thermal insulating or said cooling material is made from or with a material selected from the group consisting of at least one phase transition material and a phase change material.

22. The oscillation measurement device according to claim 16, wherein at least one of said thermal insulating or said cooling material is made from or with at least one material selected from the group of consisting of water, zeolite materials, zeolite granulates, perlite materials, perlite granulates, foam materials, carbon foam materials, and combinations thereof.

23. The oscillation measurement device according to claim 17, further comprising vanes for at least one of:
bracing said innermost container outwardly against an inner side of said outermost container; or
bracing an inner wall of said wall zone outwardly against an inner side of an outer wall of said wall zone.

24. The oscillation measurement device according to claim 17, wherein in order to transmit oscillations inwards from an outside, a portion of said wall zone of said outermost container is constructed from an oscillation transmitting element that extends into said interior of said outermost container and is made with or from at least one material with good sound conductivity or high sound velocity and low thermal conductivity.

25. The oscillation measurement device according to claim 24, wherein said oscillation transmitting element is in direct mechanical contact with said wall zone of at least one said insulating container positioned more inwardly.

26. The oscillation measurement device according to claim 17, wherein at least one of each said wall zone or a respective said wall is designed with at least one of partial mirroring or complete mirroring including on an outer side thereof.

27. The oscillation measurement device according to claim 16, wherein at least one of said thermal insulating or said cooling material is made from or with at least one material having a thermal conductivity in a range from less than about 3 W/m K.

28. The oscillation measurement device according to claim 16, wherein at least one of said thermal insulating or said cooling material is made from or with at least one material having low thermal conductivity in a range from less than about 0.3 W/m K.

29. The oscillation measurement device according to claim 21, wherein said material is at least one of a solid-liquid transition or a liquid-gas transition.

30. The oscillation measurement device according to claim 21, wherein said material has a high phase change enthalpy or a high phase transition enthalpy, in a range from about 25 kJ/mol or higher.

31. The oscillation measurement device according to claim 17, wherein in order to transmit oscillations inwards from an outside, a portion of said wall zone of said outermost insulating container is constructed from an oscillation transmitting element that extends into said interior of said outermost container and is made with or from at least one material selected from the group consisting of a stone material, granite and a slab of stone.

32. An arc furnace configuration, comprising:
an arc furnace;
at least one arc electrode being at least partially insertable or fully inserted into said arc furnace; and
an oscillation measurement device for measuring oscillations at said at least one arc electrode.

33. The arc furnace configuration according to claim 32, wherein said at least one arc electrode is one of a plurality of arc electrodes configured with one common said oscillation measuring device.

34. The arc furnace configuration according to claim 32, wherein said oscillation measurement device has means for carrying out an oscillation measurement on said at least one arc electrode.

35. The arc furnace configuration according to claim 32, wherein:
data returned by said oscillation measuring device may be recorded and evaluated; and
an operation of the arc furnace configuration having said arc furnace is at least one of controllable or adjustable, including with a feedback function, according to the method of claim 1.

36. The arc furnace configuration according to claim 32,
further comprising a holder for said arc electrode;
further comprising a cooling device for said holder;
further comprising a conveyor element for said arc electrode;
wherein said oscillation measurement device is at least one of:
attached directly or indirectly to an area that is, at least during operation, outside of said arc furnace or an area or end of said arc electrode farthest from said furnace vessel;
designed for contactless measurement tapping directly or indirectly, at least during operation, outside of said arc furnace or an area or end of said arc electrode farthest from said arc furnace;
attached directly or indirectly to said holder for said arc electrode, including to an area of said cooling device for said holder;
designed for contactless measurement tapping directly or indirectly on said holder for said arc electrode, including on an area of said cooling device for said holder;
attached directly or indirectly to said conveyor element for said arc electrode; or
designed for contactless measurement tapping directly or indirectly on said conveyor element of said arc electrode.

37. The arc furnace configuration according to claim 32, wherein:
said at least one arc electrode is one of a plurality of arc electrodes; and
said measuring device is one of a plurality of measuring devices each assigned to a respective one of said arc electrodes.
